(19) United States
(12) Patent Application Publication
(10) Pub. No.: US 2018/0240933 A1
(43) Pub. Date: Aug. 23, 2018

(54) METHOD OF MANUFACTURING LIGHT EMITTING ELEMENT

(71) Applicant: NICHIA CORPORATION, Anan-shi (JP)

(72) Inventors: Yoshitaka SUMITOMO, Anan-shi (JP); Katsuyuki KAWABATA, Anan-shi (JP); Naoto INOUE, Anan-shi (JP)

(73) Assignee: NICHIA CORPORATION, Anan-shi (JP)

(21) Appl. No.: 15/899,095

(22) Filed: Feb. 19, 2018

(30) Foreign Application Priority Data
Feb. 20, 2017 (JP) 2017-029482

(51) Int. Cl. H01L 33/00; H01L 33/46

(52) U.S. Cl. CPC H01L 33/005; H01L 33/16; H01L 2933/0025; H01L 33/46

(57) ABSTRACT

A method of manufacturing a light emitting element includes: providing a wafer that comprises: a substrate having a first main surface and a second main surface, a dielectric multilayer film on the first main surface, and a semiconductor structure on the second main surface; focusing laser light onto an inner portion of the substrate from a first main surface side of the substrate, to simultaneously form a modified region in the substrate and remove a portion of the dielectric multilayer film; and cleaving the wafer at a portion where the modified region is formed to obtain a plurality of light emitting elements.

### CROSS-REFERENCE TO RELATED APPLICATIONS

The present application claims priority to Japanese Patent Application No. 2017-029482, filed on Feb. 20, 2017, the contents of which are hereby incorporated by reference in their entirety.

### BACKGROUND

### 1. Technical Field

The present disclosure relates to a method of manufacturing a light emitting element.

### 2. Description of Related Art

In JP 2014-107485 A, a portion of a metal film in a reflecting layer on a substrate is removed, and thereafter, laser light is focused onto an inner portion of the substrate via a multilayer film in the reflecting layer, so that a modified region is formed. JP 2014-107485 A also describes cleaving the substrate using the modified region.

However, in the above-described method of manufacturing, the substrate is cleaved in the state where the multilayer film is disposed on the entire substrate, so that chipping may occur at the periphery of the multilayer film. Accordingly, an object of the present disclosure is to provide a method of manufacturing a light emitting element with which chipping of the multilayer film can be reduced and manufacturing steps are simplified.

### SUMMARY

A method of manufacturing a light emitting element according to one embodiment of the present disclosure includes: providing a wafer including a substrate having a first main surface and a second main surface, a dielectric multilayer film on the first main surface, and a semiconductor structure on the second main surface; focusing laser light onto an inner portion of the substrate from the first main surface side of the substrate, to form a modified region inside the substrate and simultaneously to remove a portion of the dielectric multilayer film; and cleaving the wafer at a portion where the modified region is formed to obtain a plurality of light emitting elements.

According to the above-described method, the modified region inside the substrate can be formed and a portion of the dielectric multilayer film on the first main surface side of the substrate can be removed. Thus, the manufacturing steps can be simplified and manufacturing yields can be improved. Further, removal of a portion of the dielectric multilayer film allows for reducing chipping of the dielectric multilayer film during cleaving the wafer.

### BRIEF DESCRIPTION OF THE DRAWINGS

FIG. 1 is a top view schematically showing a wafer used in a method of manufacturing a light emitting element according to a first embodiment.

FIG. 2 is an enlarged top view schematically showing a main part of the wafer used in the method of manufacturing the light emitting element according to the first embodiment.

FIG. 3 is a cross-sectional view schematically showing the wafer used in the method of manufacturing the light emitting element according to the first embodiment, showing the cross-section taken along a line III-III in FIG. 2.

FIG. 4 is a cross-sectional view schematically showing a light emitting element obtained by using the method of manufacturing the light emitting element according to the first embodiment.

FIG. 5 is a cross-sectional view schematically showing an example of irradiating an inner portion of a wafer with laser light.

FIG. 6 is a cross-sectional view schematically showing the example of irradiating an inner portion of the wafer with laser light.

FIG. 7 is a cross-sectional view schematically showing an example of scanning the wafer with laser light and irradiating an inner portion of the wafer with the laser light.

FIG. 8 is a cross-sectional perspective view schematically showing the light emitting element obtained by using the method of manufacturing the light emitting element according to the first embodiment.

FIG. 9 is a top view schematically showing the method of manufacturing the light emitting element according to the first embodiment.

FIG. 10 is a cross-section view schematically showing a method of manufacturing a light emitting element according to a second embodiment.

### DETAILED DESCRIPTION OF EMBODIMENTS

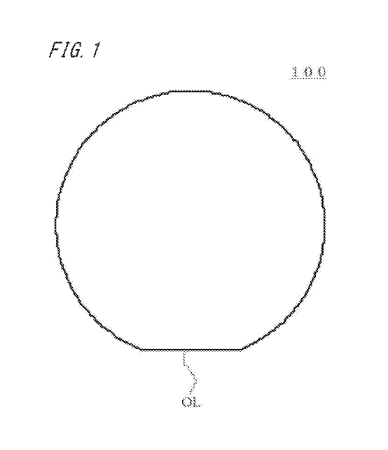

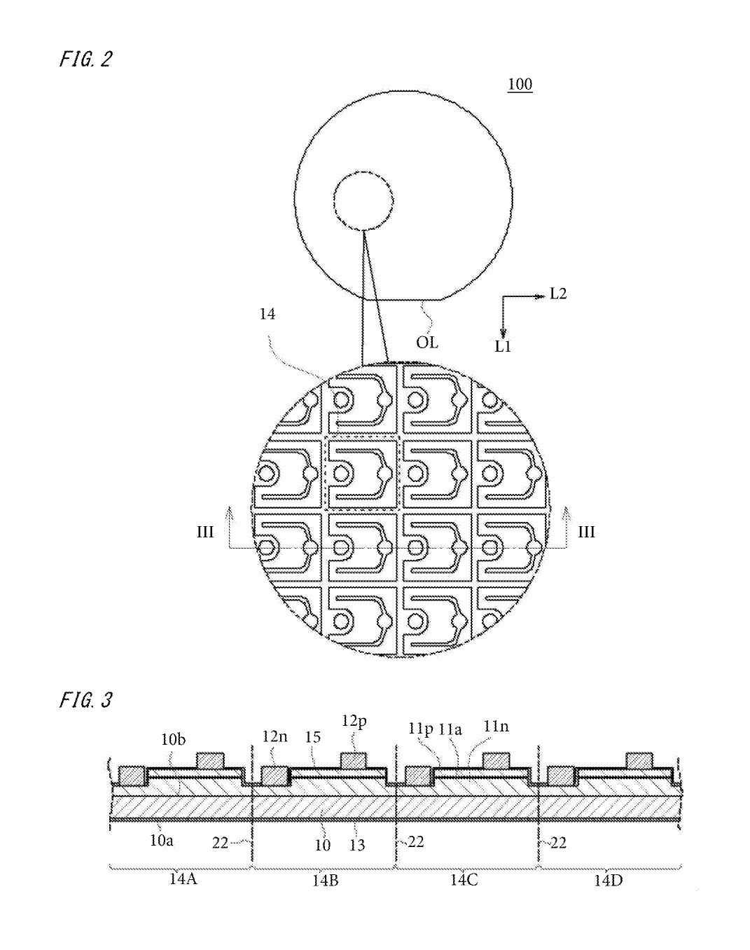

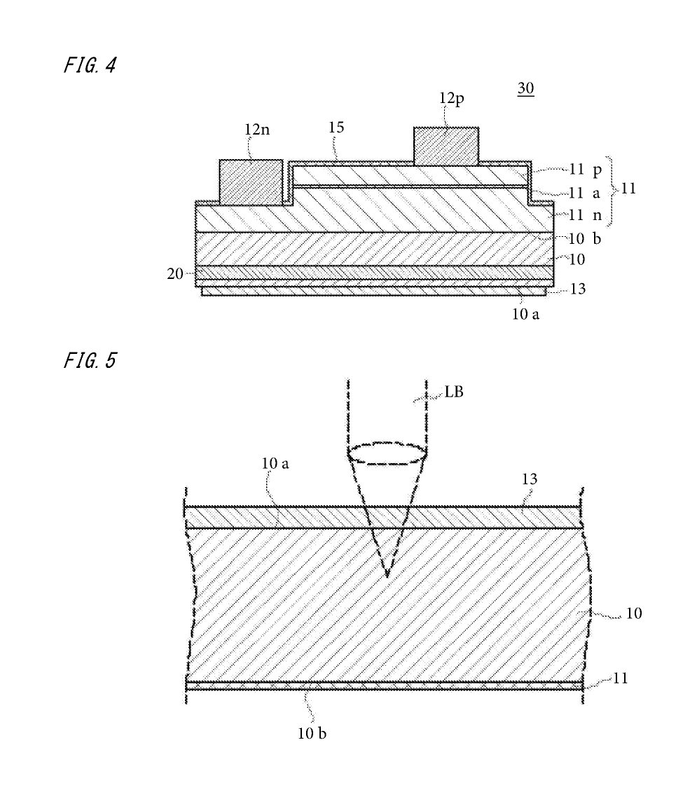

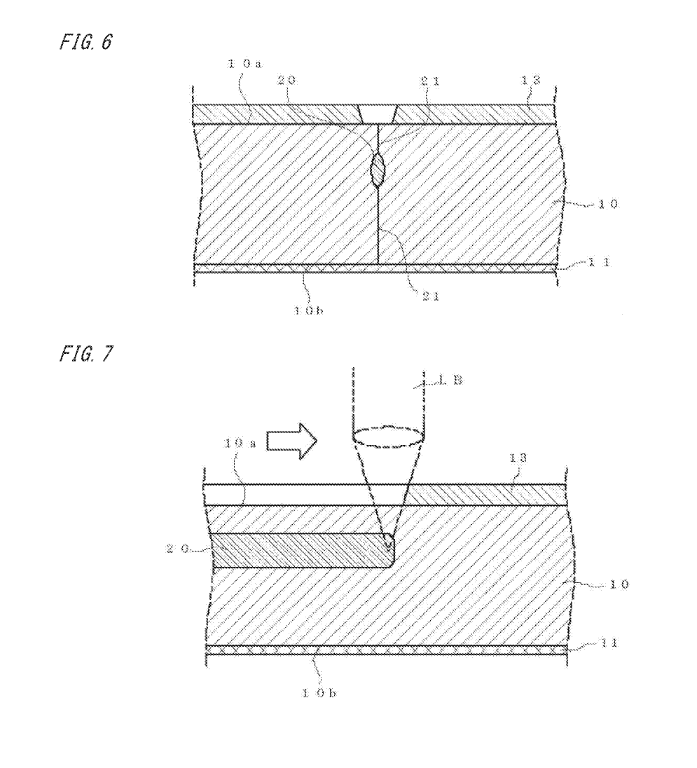

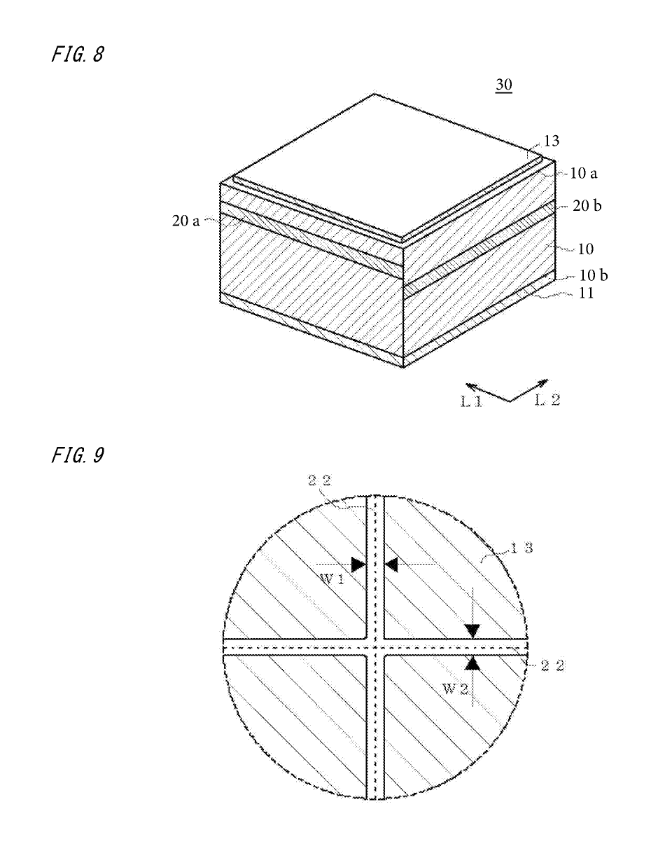

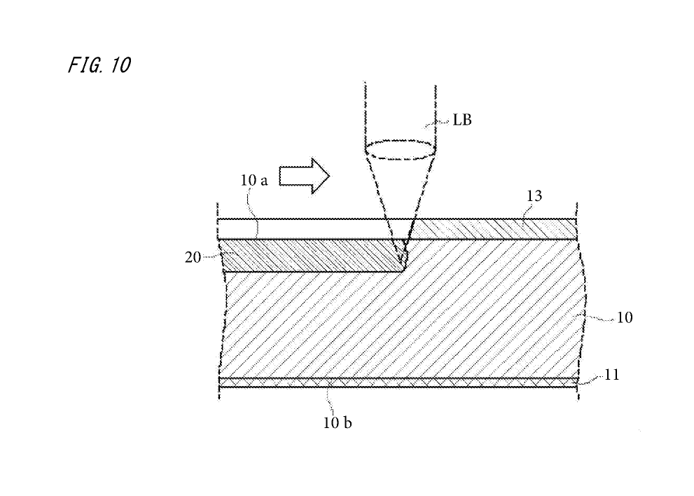

FIG. 1 is a top view schematically showing a wafer 100 used in a method of manufacturing a light emitting element according to a first embodiment. FIG. 2 is an enlarged top view schematically showing a main part of the wafer 100. FIG. 3 is a cross-sectional view schematically showing the wafer used in the method of manufacturing the light emitting element according to the first embodiment taken along line III-III in FIG. 2. FIG. 4 is a cross-sectional view schematically showing light emitting elements 30 obtained by using the method of manufacturing the light emitting element according to the first embodiment. FIG. 5 is a cross-sectional view schematically showing an example of irradiating an inner portion of the wafer 100 with laser light. FIG. 6 is a cross-sectional view schematically showing an example of irradiating an inner portion of the wafer 100 with laser light, for describing the manner of forming modified regions 20 and simultaneously removing a portion of a dielectric multilayer film 13. FIG. 7 is a cross-sectional view schematically showing an example of scanning the wafer 100 with laser light and irradiating an inner portion of the wafer 100 with laser light. FIG. 8 is a cross-sectional perspective view schematically showing the light emitting element 30. FIG. 9 is an enlarged top view of a part of the wafer 100, for describing an example where a portion of the dielectric multilayer film 13 is removed. FIG. 10 is a cross-sectional view schematically showing a method of manufacturing a light emitting element according to a second embodiment.

The drawings schematically show embodiments, and therefore, the scale, interval, positional relationship and the like of the members may be exaggerated. Further, the scale or interval between the members may not correspond between a plan view and a corresponding section view. Further, in the description below, the same or similar members are denoted by the same designations and the same reference numerals, and a detailed description thereof will be omitted as appropriate.

### First Embodiment

A method of manufacturing a light emitting element according to the present embodiment includes: (A) providing a wafer 100 including a substrate 10 having a first main surface 10a and a second main surface 10b, a dielectric multilayer film 13 on the first main surface 10a, and a semiconductor structure 11 on the second main surface 10b; (B) focusing laser light onto an inner portion of the substrate 10 from a first main surface 10a side of the substrate 10 to form a modified region 20 inside the substrate 10 and simultaneously remove a portion of the dielectric multilayer film 13; and (C) cleaving the wafer 100 at a portion where the modified region 20 is formed to obtain a plurality of light emitting elements 30.

According to such a method, the modified region 20 is formed inside the substrate 10 while portion of the dielectric multilayer film 13 on the first main surface 10a side of the substrate is removed, so that manufacturing steps can be simplified and yield can be improved. Further, because a portion of the dielectric multilayer film 13 is removed, chipping at the periphery of the dielectric multilayer film 13 that may otherwise occur in cleaving the wafer 100 becomes less likely to occur. This will be described below in detail.

When a wafer having a dielectric multilayer film on a main surface side of a substrate is irradiated with laser light to form a modified region inside the substrate, chipping may occur at the periphery of the dielectric multilayer film during cleaving of the wafer. One cause of this may be extension of a crack from the modified region to reach the dielectric multilayer film, where the crack is formed in an unintended direction. When the wafer is cleaved with the dielectric multilayer film including such a crack, the dielectric multilayer film may not be cleaved into a desired shape, and chipping may occur at a portion of the periphery of the dielectric multilayer film.

Accordingly, as shown in FIGS. 6 and 7, the wafer 100 is irradiated with laser light, which forms the modified region 20 in the substrate 10 and simultaneously removes a portion of the dielectric multilayer film 13 at the region scanned with the laser light, that is, a portion of the dielectric multilayer film 13 on each division-planning line 22. Thus, forming the modified region 20 and removing a portion of the dielectric multilayer film 13 can be performed in the same step. Further, a portion of the dielectric multilayer film 13 at each division-planning line 22 can be removed before the wafer 100 is cleaved, so that chipping at the periphery of the dielectric multilayer film 13 of the obtained light emitting elements 30 can be reduced. As a result, the light emitting elements 30 in which the light extraction efficiency is maintained can be produced with improved yields.

A detailed description of the method of manufacturing the light emitting element according to the present embodiment will be given below.

The wafer 100 in which the dielectric multilayer film 13 and the semiconductor structure 11 are disposed on the substrate 10 is provided. The substrate 10 has a first main surface 10a and a second main surface 10b.

The dielectric multilayer film 13 is disposed on the first main surface 10a, and the semiconductor structure 11 is disposed on the second main surface 10b. As shown in the top view of FIG. 1, the wafer 100 has a substantially circular shape in a top view, and has an orientation flat surface OL where a portion of the outer circumference of the wafer 100 is flat. The size of the wafer 100 is in a range of, for example, about Φ50 mm to 100 mm inclusive.

For the substrate 10, a substrate can be used on which semiconductor layers in a semiconductor structure 11 can be grown. Hereinafter, a description is given of an example where a sapphire substrate is employed as the substrate 10. For the substrate 10, a c-plane sapphire substrate is used in which the second main surface 10b is c-plane represented by a Miller index of (0001). Examples of the c-plane sapphire substrate in the present specification include an off-axis substrate in which the second main surface 10b is inclined with respect to the c-plane at an angle of about 5° or less. The substrate 10 may have a thickness in a range of, for example, about 50 μm to 2 mm. Alternatively, a substrate 10 having a thickness in a range of about 200 μm to 2 mm may be provided, the semiconductor structure 11 may be formed thereon, and thereafter, polishing or the like may performed to reduce the thickness of the substrate 10 so as to be in a range of about 50 μm to 400 μm, preferably 100 μm to 300 μm.

The semiconductor structure 11 includes an n-type semiconductor layer, an active layer 11a, and a p-type semiconductor layer, each of which is a nitride semiconductor such as InₓAl_{y}Ga_{1-x-y}N (0≤X, 0≤Y, X+Y<1). The peak emission wavelength of the light emitted by the active layer 11 a is in a range of, for example, 360 nm to 650 nm.

Note that, as shown in the cross-sectional view of FIG. 4, each of the light emitting elements 30 obtained by cleaving the wafer 100 using to the method of manufacturing according to the present embodiment includes a semiconductor structure 11 having a plurality of semiconductor layers layered on the second main surface 10b of the substrate 10. More specifically, the light emitting element 30 includes the substrate 10 and the semiconductor structure 11, which includes an n-side semiconductor layer 11n, an active layer 11a, a p-side semiconductor layer 11p layered in order from the second main surface 10b side on the second main surface 10b of the substrate 10. An n-electrode 12n is electrically connected to the n-side semiconductor layer 11n, and a p-electrode 12p is electrically connected to the p-side semiconductor layer 11p. The semiconductor structure 11 is covered with an insulating film 15. The light emitting element 30 includes a dielectric multilayer film 13 on the first main surface 10a of the substrate 10, and the area where the dielectric multilayer film 13 is disposed is smaller than the area of the first main surface 10a of the substrate 10. Further, at the lateral surface of the substrate 10, the region where the modified regions 20 are formed can be recognized. Note that, in FIG. 4, the region where the plurality of modified regions 20 is formed is shown as a band-like region. Further, also in FIGS. 7, 8, 10, each of the plurality of modified regions 20 is shown as a band-like region.

The dielectric multilayer film 13 on the first main surface 10a is a layered film of a plurality of dielectric films, and functions as a reflecting film that reflects light emitted from the semiconductor structure 11. The dielectric multilayer film 13 includes, for example, at least two selected from the group consisting of an SiO₂ film, a TiO₂ film, and an Nb₂O₅ film. The number of dielectric film layers included in the dielectric multilayer film 13, and a thickness and a material of each layer can be selected as appropriate in accordance with the wavelength of light to be reflected on the dielectric film. With the dielectric multilayer film 13 made of at least two selected from the group consisting of an SiO₂ film, a TiO₂ film, and an Nb₂O₅ film and designed to reflect light, particularly to reflect light of the peak emission wavelength of light emitted by the active layer 11a, the luminance of the obtained light emitting elements 30 can be improved.

In FIG. 2, a top view of the wafer 100 when viewed from the first main surface 10a side and an enlarged view of a part of the wafer 100 are shown in combination. FIG. 3 corresponds to a cross-sectional view taken along a line III-III in FIG. 2, and shows a cross-sectional view of a plurality of light emitting element regions 14A to 14D. As shown in FIG. 2, in the wafer 100, a plurality of light emitting element regions 14 is two-dimensionally arranged. Each of the plurality of light emitting element regions 14 corresponds to a respective one of the light emitting elements 30 obtained by cleaving the wafer 100. The wafer 100 includes, for example, about three thousand to fifty thousand light emitting element regions 14.

As shown in FIG. 2, the plurality of light emitting element regions 14 is arranged in a matrix along a first direction L1 perpendicular to the orientation flat OL of the substrate 10, and a second direction L2 parallel to the orientation flat OL of the substrate 10. For the substrate 10, a sapphire substrate of which second main surface 10b is the c-plane is employed.

In FIG. 2, the first direction L1 indicated by arrow L1 is parallel to the a-axis of the sapphire substrate.
The second direction L2 indicated by arrow L2 in FIG. 2 is parallel to the m-axis of the sapphire substrate.

Next, the substrate 10 is irradiated with laser light, which forms the modified regions 20 for cleaving the wafer 100 and simultaneously removes a portion of the dielectric multilayer film 13. Each of FIGS. 5 and 6 shows the state of focusing laser light onto an inner portion of the substrate 10 from the first main surface 10a side, and thus forming the modified regions 20. FIG. 7 shows the manner of scanning the substrate 10 with laser light, which forms the modified regions 20 inside the substrate 10 and simultaneously removes a portion of the dielectric multilayer film 13. The laser light is transmitted through the dielectric multilayer film 13, and focused on an inner portion of the substrate 10, so that a portion of the dielectric multilayer film 13 at the region irradiated with the laser light is removed. In the present embodiment, pulsed laser light is employed as the laser light, and the substrate 10 is scanned with the laser light along the division-planning lines 22 each representing a virtual division-planned portion between adjacent ones of the light emitting element regions 14. Thus, a plurality of modified regions 20 along the division-planning line 22 are formed. By repeating such scanning along the first direction L1 and the second direction L2, the plurality of modified regions 20 are formed along the plurality of division-planning lines 22 inside the substrate 10, and simultaneously, a portion of the dielectric multilayer film 13 above each division-planning line 22 is removed. In this manner, forming of the modified regions 20 and removing of a portion of the dielectric multilayer film 13 can be performed simultaneously by a single laser light irradiation, which allows for achieving simplified manufacturing steps. Consequently, manufacturing yields can be improved. Further, a portion of the dielectric multilayer film 13 above division-planning lines 22 is removed, so that the wafer 100 can be cleaved in a state where the dielectric multilayer film 13 is not present in a region above the division-planning lines 22, where otherwise the crack 21 extending from the modified regions 20 reaches and an unintended crack is formed. This allows for inhibiting occurrence of chipping at the periphery of the dielectric multilayer film 13 of each of obtained light emitting elements 30. Such chipping of the dielectric multilayer film 13 is a cause of reduction of the light extraction efficiency and impairment of appearance of the light emitting elements 30.

As shown in FIG. 6, by forming the modified regions 20, the crack 21 is generated that extends from the modified regions 20 to the first main surface 10a side and the second main surface 10b of the substrate 10. In the step of cleaving the wafer 100, which will be described below, the wafer 100 is cleaved starting from the modified regions 20 and the crack 21 generated in the substrate 10. The crack 21 extending from the modified regions 20 preferably reaches the second main surface 10b. This allows for inhibiting the crack 21 from extending in an unintended direction during cleaving the wafer 100 by applying external force, so that occurrence of chipping of the obtained light emitting elements 30 can be reduced.

The inner portion of the substrate where the laser light is focused is preferably located at a position in a range of about 30 μm to 60 further preferably a range of about 40 μm to 50 μm from the first main surface 10a in a thickness direction of the substrate 10. Focusing laser light onto an inner portion of the substrate 10 at a position of 30 μm or more from the first main surface 10a in the thickness direction of the substrate 10 allows for widening an irradiation region on the dielectric multilayer film 13 with the laser light, and accordingly, a portion of the dielectric multilayer film 13 with a relatively greater width can be removed. Further, focusing laser light onto an inner portion of the substrate 10 at a position 60 μm or less from the first main surface 10a in the thickness direction of the substrate 10 allows for facilitating an increase in the energy density of the laser light with which the dielectric multilayer film 13 is irradiated, and accordingly, a portion of the dielectric multilayer film 13 can be efficiently removed.

During scanning of the wafer 100 with the laser light in the first direction L1 and the second direction L2 to form the modified regions 20, as shown in FIG. 8, preferably, the modified regions 20 include first modified regions 20a formed along the first direction L1 and second modified regions 20b formed along the second direction L2, and first modified regions 20a are positioned closer to the first main surface 10a than the second modified regions 20b. Thus, in the first direction L1, along which the crack 21 extending from the modified regions 20 tends to be generated with inclination with respect to the m-plane of the sapphire substrate, the distance between the crack 21 and the first main surface 10a is shortened, so that the crack 21 can easily reach the region in the first main surface 10a from which a portion of the dielectric multilayer film 13 has been removed. Thus, occurrence of chipping of the dielectric multilayer film 13 in cleaving the wafer 100 can be reduced. Note that, FIG. 8 shows an example of the light emitting element 30, in which the first modified regions 20a and the second modified regions 20b that have different depths in the thickness direction of the substrate 10 are formed at the lateral surfaces of the light emitting element 30 under the above-described laser light processing conditions. In the thickness direction of the substrate 10, the first modified regions 20a and the second modified regions 20b do not overlap with each other in FIG. 8, but the first modified regions 20a and the second modified regions 20b may overlap with each other.

A portion of the dielectric multilayer film 13 removed by irradiation of the laser light preferably has a width in a range of about 6 μm to 12 μm, and further preferably about 8 μm to 10 μm. The expression “width of the dielectric multilayer film 13” as used herein refers to a width thereof in a top view indicated by W1 or W2 in FIG. 9, in a direction perpendicular to the division-planning lines 22. Note that, the regions hatched in FIG. 9 are not indicated as a cross-sectional view, and are indicated as the regions where the dielectric multilayer film 13 is provided. With the width of a portion of the dielectric multilayer film 13 removed by irradiation of the laser light of 6 μm or greater, the crack 21 can easily reach the region in the first main surface 10a from which the dielectric multilayer film 13 has been removed. With the width of a portion of the dielectric multilayer film 13 removed by irradiation of the laser light of 10 μm or less, reduction in the light extraction efficiency of the light emitting element 30 attributed to excessive removal of the dielectric multilayer film 13 can be inhibited.

In accordance with the thickness of the substrate 10 and the like, the peak power of the laser light is preferably in a range of about 7.0 MW to 15.0 MW, further preferably in a range of about 7.0 MW to 13.0 MW, and still further preferably a range of about 7.0 MW to 10.0 MW inclusive. With the peak power of the laser light of 7.0 MW or greater, which is a relatively great value, the removing of the dielectric multilayer film 13 and the forming of the modified regions 20 can be efficiently performed. With the peak power of the laser light of 15.0 MW or less, damage to the semiconductor structure 11 attributed to irradiation of laser light can be reduced. Note that, if the thickness of the substrate 10 is relatively small, the peak power of the laser light can be 7.0 MW or less. As used herein, the “peak power” is a value calculated using the value of the pulse energy and the value of the pulse width of laser light and is calculated from “peak power={(pulse energy×10⁻⁶)/(pulse width×10⁻¹⁵)}/1000”. In the present embodiment, calculation is performed in which the unit of the peak power is “MW”, the unit of the pulse energy is “μJ”, and the unit of the pulse width is “fsec”. In general, the peak power of the laser light used during forming of the modified regions 20 inside the substrate 10 is in a range of about 0.8 MW to 1.0 MW, which is relatively small values compared with the present embodiment.

As the peak wavelength of the laser light, a wavelength of light that transmits through the dielectric multilayer film 13 and the substrate 10 is selected. For example, laser light having the peak wavelength in a range of 800 μm to 1200 nm may be employed.

As the laser light source, a laser light source configured to generate pulsed laser light, a continuous wave laser, or the like, which can cause multiphoton absorption, may be employed. In the present embodiment, a laser light source configured to generate pulsed laser light, such as a femtosecond laser or a picosecond laser, is employed. For the laser light source, a titanium sapphire laser, an Nd: YAG laser, an Nd: YVO4 laser, an Nd: YLF laser or the like may be used.

Next, the wafer 100 is cleaved at the region where the modified regions 20 are formed, so that a plurality of light emitting elements 30 is obtained. In the wafer 100, a plurality of modified regions 20 are formed along a plurality of division-planning lines 22, and the wafer 100 is cleaved using the modified regions 20 and the crack 21 extending from the modified regions 20. Examples of the method of cleaving the wafer 100 include expanding a dicing tape supporting the wafer 100 in the radial direction of the wafer 100, and pressing the edge of a plate-shaped blade against the virtual division-planning line 22 to cleave the wafer 100 at the region where the crack 21 exists.

### Second Embodiment

A method of manufacturing a light emitting element according to a second embodiment of the present invention will be described below in detail. In the first embodiment, the wafer 100 is scanned with the laser light under the same processing conditions both in the first direction L1 and the second direction L2.

On the other hand, the second embodiment is mainly different from the first embodiment in that the scanning is performed under different processing conditions between the first direction L1 and the second direction L2.

In the present embodiment, in the step of irradiating the wafer 100 with the laser light to form the modified regions 20 and remove a portion of the dielectric multilayer film 13, when the wafer 100 is scanned with the laser light along the first direction L1, that is, when scanning is performed along the direction parallel to the a-axis of the sapphire substrate, as shown in FIG. 10, the modified regions 20 are formed so as to reach the first main surface 10a. In the case in which the sapphire substrate is scanned with the laser light along the direction parallel to the a-axis, the crack 21 generated from the modified regions 20 tends to be inclined with respect to the m-plane of the sapphire substrate. Accordingly, even if a portion of the dielectric multilayer film 13 is removed by irradiation of the laser light, the crack 21 may not reach the region in the first main surface 10a where the dielectric multilayer film 13 has been removed. That is, the crack 21 may reach the region in the first main surface 10a where the dielectric multilayer film 13 is disposed. If the wafer 100 is cleaved in a state in which a crack 21 is formed in such a region, chipping may occur in a portion of the light emitting element 30 obtained by the cleaving of the wafer 100, or a portion of the dielectric multilayer film 13 to be left in the light emitting element 30. However, in the present embodiment, the modified regions 20 are formed so as to reach the first main surface 10a, the crack 21 can be formed without inclining with respect to the m-plane of the sapphire substrate, and the wafer 100 can be cleaved at the region where the dielectric multilayer film 13 has been removed. Accordingly, chipping of the dielectric multilayer film 13 occurring during cleaving of the wafer 100 can be reduced.

On the other hand, when the sapphire substrate is scanned with the laser light along the direction parallel to the second direction L2, that is, the m-axis of the sapphire substrate, the modified regions 20 are formed so as not to reach the first main surface 10a. Compared with the case in which the sapphire substrate is scanned with the laser light along the direction parallel to the a-axis of the sapphire substrate, the scanning along the direction parallel to the m-axis less easily allows for generating the crack 21 from the modified regions 20 as being inclined relative to the a-plane of the sapphire substrate. Further, in the case in which the modified regions 20 are formed so as to reach the first main surface 10a, the modified regions 20 appearing at the first main surface 10a tend to have a zigzag shape.

If such a wafer 100 is cleaved, the obtained light emitting element 30 may have a zigzag periphery, or chipping may occur. Accordingly, the modified regions 20 is formed to reach the first main surface 10a in the first direction L1 and not to reach the first main surface 10a in the second direction L2, so that chipping in the dielectric multilayer film 13 in the first direction L1 can be reduced and reduces roughening at the periphery of the substrate 10 in the second direction L2.

The second embodiment can exhibit the effect similar to that exhibited by the first embodiment.

### EXAMPLE

Next, a method of manufacturing a light emitting element according to an Example will be described.

A wafer was provided in which a sapphire substrate was used for the substrate 10, the dielectric multilayer film 13 including twenty-one dielectric film layers was disposed on the first main surface 10a of the substrate 10, and the semiconductor structure 11 including a plurality of nitride semiconductor layers was disposed on the second main surface 10b, The sapphire substrate having a thickness of 200 μm was used. For the dielectric multilayer film 13, a layered film in which eleven SiO₂ films and ten TiO₂ films were alternately layered was used. The optical design of the dielectric multilayer film 13 was selected so as to transmit laser light used for forming the modified regions 20 and removing a portion of the dielectric multilayer film 13, and to reflect light having the peak wavelength of light from the semiconductor structure 11.

Next, from the first main surface 10a side, the substrate 10 was irradiated with laser light while being scanned with the laser light along a plurality of division-planning lines 22 extending in the first direction L1 and the second direction L2. The conditions for this processing are as follows.

### Conditions for Processing

Peak wavelength of laser light: approximately 1000 nm

The peak power of the laser light during scanning along the first direction L1 and the second direction L2: about 7.9 MW

The pulse width of the laser light during scanning along the first direction L1 and the second direction L2: 700 fsec

The pulse energy of the laser light during scanning along the first direction L1 and the second direction L2: 5.5 μJ

The laser shot interval during scanning along the first direction L1 and the second direction L2: 2.0 μm

The positions where the laser light is focused along the first direction L1 and the second direction L2: 50 μm from the first main surface 10a side

The number of scanning of the laser light for each division-planning line: 4

The “laser shot interval” refers to an interval between the light-focusing positions, where laser light is focused when adjacent ones of the plurality of modified regions 20 are formed. Further, the laser shot interval can be adjusted as appropriate by adjusting the feeding speed of the laser light in scanning and the repetition frequency.

Under the above-described processing conditions, the wafer 100 was irradiate with the laser light, so that the modified regions 20 were formed inside the substrate 10 along the division-planning lines 22 and simultaneously a portion of the dielectric multilayer film 13 provided on the division-planning line 22 was removed.

Thereafter, the wafer 100 was cleaved at the region where the modified regions 20 were formed so that a plurality of light emitting elements 30 was obtained.

### COMPARATIVE EXAMPLE

A method of manufacturing a light emitting element according to a Comparative Example is similar to that of the Example except for changes in processing conditions during the forming of the modified regions and the removing of a portion the dielectric multilayer film, which are caused by irradiation of laser light. More specifically, while the peak power of the laser light during scanning in the first direction L1 and the second direction L2 was approximately 7.9 MW in the Example, the peak power of the laser light was approximately 5.0 MW in the Comparative Example. In the Comparative Example, the pulse width of the laser light was 1000 fsec, and the pulse energy was 5.0 μJ.

In the Comparative Example, the modified regions were formed to some extent in the substrate, but removal of a portion of the dielectric multilayer film was failed. Thus, the dielectric multilayer film was remained in a region above the division-planning lines, and the portion of the dielectric multilayer film above the division-planning lines was discolored by being irradiated with the laser light.

In the Comparative Example, failure to remove a portion of the dielectric multilayer film by irradiation of the laser light is considered to be due to lower energy density of the laser light with which the dielectric multilayer film was irradiated than that in the Example. This is assumed to be cause of failure of the removal of the dielectric multilayer film 13.

As described above, by using the method of manufacturing the light emitting element according to the Comparative Example, a portion of the dielectric multilayer film 13 was not removed simultaneously with forming of the modified regions 20. Further, in the light emitting element obtained by using the method of manufacturing the light emitting element according to the Comparative Example, chipping tended to occur at the periphery of the dielectric multilayer film, compared with the dielectric multilayer film 13 in the light emitting element 30 obtained by using the method of manufacturing the light emitting element according to the Example.

As shown in the above, a light emitting element is illustrated in accordance with the first and second embodiments and the Example, but the scope of the present disclosure is not limited to the above description, and should be broadly understood based on the claims. Further, the scope of the present invention may include various modifications and changes based on the above description.

What is claimed is:

1. A method of manufacturing a light emitting element, the method comprising:
providing a wafer that comprises:
a substrate having a first main surface and a second main surface,
a dielectric multilayer film on the first main surface, and
a semiconductor structure on the second main surface;
focusing laser light onto an inner portion of the substrate from a first main surface side of the substrate, to simultaneously form a modified region in the substrate and remove a portion of the dielectric multilayer film; and
cleaving the wafer at a portion where the modified region is formed to obtain a plurality of light emitting elements.

2. The method according to claim 1, wherein:
the substrate is made of sapphire in which the second main surface is a c-plane, and
the step of focusing laser light comprises:
scanning the wafer with the laser light in a first direction that is parallel to an a-axis of the substrate, to form a first plurality of the modified regions along the first direction; and
scanning the wafer with the laser light in a second direction that is parallel to an m-axis of the substrate, to form a second plurality of the modified regions along the second direction, and
in the step of scanning the wafer in the first direction, the modified regions are formed so as to reach the first main surface.

3. The method according to claim 2, wherein, in the step of scanning the wafer in the second direction, the modified regions are formed so as not to reach the first main surface.

4. The method according to claim 2, wherein, in a thickness direction of the substrate, (i) a distance between the modified regions formed in the step of scanning the wafer in the first direction and the first main surface is smaller than (ii) a distance between the modified regions formed in the step of scanning the wafer in the second direction and the first main surface.

5. The method according to claim 3, wherein, in a thickness direction of the substrate, (i) a distance between the modified regions formed in the step of scanning the wafer in the first direction and the first main surface is smaller than (ii) a distance between the modified regions formed in the step of scanning the wafer in the second direction and the first main surface.

6. The method according to claim 1, wherein, in the step of focusing laser light, a width of the removed portion of the dielectric multilayer film is in a range of 8 μm to 10 μm.

7. The method according to claim 2, wherein, in the step of focusing laser light, a width of the removed portion of the dielectric multilayer film is in a range of 8 μm to 10 μm.

8. The method according to claim 3, wherein, in the step of focusing laser light, a width of the removed portion of the dielectric multilayer film is in a range of 8 μm to 10 μm.

9. The method according to claim 4, wherein, in the step of focusing laser light, a width of the removed portion of the dielectric multilayer film is in a range of 8 μm to 10 μm.

10. The method according to claim 1, wherein, in the step of focusing laser light, a peak power of the laser light is in a range of 7.0 MW to 15.0 MW.

11. The method according to claim 2, wherein, in the step of focusing laser light, a peak power of the laser light is in a range of 7.0 MW to 15.0 MW.

12. The method according to claim 3, wherein, in the step of focusing laser light, a peak power of the laser light is in a range of 7.0 MW to 15.0 MW.

13. The method according to claim 4, wherein, in the step of focusing laser light, a peak power of the laser light is in a range of 7.0 MW to 15.0 MW.

14. The method according to claim 1, wherein the dielectric multilayer film includes at least two films selected from the group consisting of an SiO₂ film, a TiO₂ film, and an Nb₂O₅ film.

15. The method according to claim 2, wherein the dielectric multilayer film includes at least two films selected from the group consisting of an SiO₂ film, a TiO₂ film, and an Nb₂O₅ film.

16. The method according to claim 3, wherein the dielectric multilayer film includes at least two films selected from the group consisting of an SiO₂ film, a TiO₂ film, and an Nb₂O₅ film.
